(19) United States
(12) Patent Application Publication
(10) Pub. No.: US 2025/0308814 A1
(43) Pub. Date: Oct. 2, 2025

(54) FORCE ANALOG KEYBOARD SWITCH

(71) Applicant: Logitech Europe S.A., Lausanne (CH)

(72) Inventors: Frédéric Alexis Guillaume de Goumoëns, Rolle (CH); Léo Zeender, Lausanne (CH); Jan Stoeckli, Jongny (CH); Nicolas Ramond, Lurgrin (FR)

(21) Appl. No.: 18/621,776

(22) Filed: Mar. 29, 2024

(51) Int. Cl. H01H 13/70; H05K 1/16

(52) U.S. Cl. CPC H01H 13/70; H05K 1/165

(57) ABSTRACT

In some embodiments, a key structure comprises a processor, a depressible plunger configured to travel along a range of motion including a first range of motion and a second range of motion, a dampening element that compresses as the depressible plunger moves farther along the second range of motion, and a sensing element including a first sensing section configured to detect movement of the depressible plunger along the first range of motion and generate corresponding first data and a second sensing section configured to detect movement of the depressible plunger along the second range of motion and generate corresponding second data. The processor is configured to determine a position of the plunger along the first range of motion based on the first data and determine the force produced by the plunger on the dampening element, while the plunger moves along the second range of motion, based on the second data.

### BACKGROUND

Computer peripheral devices are commonplace in modern society and are typically used to convert human-induced analog inputs (e.g., touches, clicks, motions, touch gestures, button presses, scroll wheel rotations, etc.) made in conjunction with computer peripheral devices into digital signals for computer processing. A computer peripheral device, or more broadly, an input device, can include any device that can provide data and control signals to a computing system. Some non-limiting examples of input devices include computer mice, keyboards, virtual reality and/or augmented reality controllers, touch pads, remote controls, gaming controllers, joysticks, trackballs, and the like.

Input devices have undergone many marked improvements over the last several decades. In some contemporary input devices, such as keyboards, analog keys have become popular for certain applications like competitive gaming. Analog keys can provide better resolution in key press detection that extends beyond a simple make or break connection but can come at a significant increase in production cost, system complexity, and power requirements, and can often be subject to poor detection characteristics. As such, better solutions are needed.

Unless otherwise indicated herein, the materials described in this section are not prior art to the claims in this application and are not admitted as being prior art by inclusion in this section.

### BRIEF SUMMARY

In certain embodiments, a key structure can include: one or more processors, a depressible plunger configured to travel along a range of motion including a first range of motion and a second range of motion that begins after, and is colinear with, the first range of motion; a dampening element configured such that the depressible plunger contacts the dampening element at an end of the first range of motion and a beginning of the second range of motion, wherein the depressible element compresses as the depressible plunger moves farther along the second range of motion; and a sensing element including: a first sensing section configured to detect movement of the depressible plunger along the first range of motion and generate corresponding first data; and a second sensing section configured to detect movement of the depressible plunger along the second range of motion and generate corresponding second data, wherein the one or more processors are configured to: determine a position of the plunger along the first range of motion based on the first data; and determine a force produced by the plunger on the dampening element, while the plunger moves along the second range of motion, based on the second data. In some embodiments, the sensing element is a single sensing element. The first sensing section of the sensing element can be configured to be extend vertically and parallel to the first and second ranges of motion. The second sensing section of the sensing element can be configured to extend horizontally and perpendicular to the first and second ranges of motion.

In some embodiments, the key structure can further include a printed circuit board (PCB) having a flexible substrate, wherein the sensing element is configured on the flexible substrate PCB, and wherein the sensing element is comprised of a single inductive coil that spans both the first and second sensing sections of the sensing element such that portions of the single inductive coil are oriented 90° relative to one another. The key structure can further comprise a first printed circuit board (PCB) and a second PCB, wherein the first sensing section includes a first inductive coil integrated with the first PCB, wherein the second sensing section includes a second inductive coil integrated with the second PCB, wherein the first inductive coil and second inductive coil are connected in series, and wherein the first PCB is oriented orthogonally with respect to the second PCB. In some cases, the key structure can further include an electrically conductive structure configured vertically and parallel at least a portion of the first sensing section of the sensing element, the electrically conductive structure operable to bias a sensitivity of the sensing element along the first range of motion. The biasing of the electrically conductive structure may increase a linearity of the sensitivity of the sensing element along the first range of motion. The key structure can further comprise a printed circuit board (PCB), wherein a first inductive coil is integrated on a first side of the PCB closest to the plunger, and wherein the electrically conductive structure is configured on a second side of the PCB that is opposite the first side. In some aspects, determining the force produced by the plunger on the dampening element while the plunger moves along the second range of motion corresponds to an amount that the dampening element is compressed by the plunger. The key structure can further include an electrically conductive target coupled to the plunger, wherein the first and second sensing sections of the sensing element detect the movement of the plunger along the first and second ranges of motion by detecting the movement of the electrically conductive target.

In certain embodiments, a method of operating a keyboard device includes: detecting, by a first sensing section of a sensing element that is controlled by one or more processors of the keyboard device, a position of a depressible plunger of a key structure along a first range of motion; generating first data, by the sensing element, corresponding to the position of the depressible plunger along the first range of motion; detecting, by a second sensing section of the sensing element, the position of the plunger of the key structure along a second range of motion, the second range of motion beginning after, and colinear with, the first range of motion, wherein a dampening element is configured such that the depressible plunger contacts the dampening element at an end of the first range of motion and a beginning of the second range of motion, wherein the dampening element compresses as the depressible plunger moves farther along the second range of motion; generating second data, by the sensing element, corresponding to the position of the depressible plunger along the second range of motion; determining a position of the plunger along the first range of motion based on the first data; and determining a force produced by the plunger on the dampening element while the plunger moves along the second range of motion, based on the second data. In some cases, the sensing element can be a single sensing element, or multiple sensing elements. The first sensing section of the sensing element may be configured to be extend vertically and parallel to the first and second ranges of motion. In some cases, the second sensing section of the sensing element is configured to extend horizontally and perpendicular to the first and second ranges of motion.

In some embodiments, the keyboard device comprises a printed circuit board (PCB) having a flexible substrate, wherein the sensing element is configured on the flexible substrate PCB, and wherein the sensing element is comprised of a single inductive coil that spans both the first and second sensing sections of the sensing element such that portions of the single inductive coil are oriented 90° relative to one another. The keyboard device can further comprise: a first printed circuit board (PCB) and a second PCB, wherein the first sensing section includes a first inductive coil integrated with the first PCB, wherein the second sensing section includes a second inductive coil integrated with the second PCB, wherein the first inductive coil and second inductive coil are connected in series, and wherein the first PCB is oriented orthogonally with respect to the second PCB. In some embodiments, the keyboard device further comprises an electrically conductive structure configured vertically and parallel at least a portion of the first sensing section of the sensing element, the electrically conductive structure operable to bias a sensitivity of the sensing element along the first range of motion. In certain embodiments, the biasing of the electrically conductive structure increases a linearity of the sensitivity of the sensing element along the first range of motion. The keyboard device can further comprise a printed circuit board (PCB), wherein a first inductive coil is integrated on a first side of the PCB closest to the plunger, and wherein the electrically conductive structure is configured on a second side of the PCB that is opposite the first side.

The terms and expressions that have been employed are used as terms of description and not of limitation, and there is no intention in the use of such terms and expressions of excluding any equivalents of the features shown and described or portions thereof. It is recognized, however, that various modifications are possible within the scope of the systems and methods claimed. Thus, although the present system and methods have been specifically disclosed by examples and optional features, modification and variation of the concepts herein disclosed should be recognized by those skilled in the art, and such modifications and variations are considered to be within the scope of the systems and methods as defined by the appended claims.

This summary is not intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim.

The foregoing, together with other features and examples, will be described in more detail below in the following description, claims, and accompanying drawings.

### BRIEF DESCRIPTION OF THE DRAWINGS

The features of the various embodiments described above, as well as other features and advantages of certain embodiments of the present invention, will be more apparent from the following detailed description taken in conjunction with the accompanying drawings, in which:

FIG. 1 shows a simplified example of a computer system that can include any of a variety of host computing devices and computer peripheral devices, including computer peripheral devices (e.g., keyboard) that can be configured to perform aspects of the various inventive concepts described herein;

FIG. 2 shows a system for operating a computer peripheral device, according to certain embodiments;

FIG. 3 is a simplified block diagram of a host computing device, according to certain embodiments;

FIGS. 4A-4F show a key press sequence for a key structure with position and force sensing capabilities, according to certain embodiments;

FIG. 5A shows an idealized dual sensor configuration to achieve two linear sense curves, according to certain embodiments;

FIG. 5B shows a key structure with a single sensor architecture with diverging sensitivity characteristics, according to certain embodiments;

FIG. 5C shows a key structure with a single sensor architecture with modifications that linearize travel sensing, according to certain embodiments;

FIG. 6A shows a key structure with improved sensitivity due to a moveable drawbridge platform and target structure that moves with a plunger as it is depressed, according to certain embodiments;

FIG. 6B shows a key structure with improved sensitivity due to a moveable drawbridge platform and target structure that moves with a plunger as it is depressed, according to certain embodiments;

FIG. 7A shows a key structure and target configured on a plunger with separate orthogonally configured sensors, according to certain embodiments;

FIG. 7B shows a key structure and target configured on a plunger with a single sensor having orthogonally configured sections, according to certain embodiments;

FIG. 7C shows a key structure with a vertically and horizontally elongated target, according to certain embodiments;

FIG. 8A shows a sensor structure with a single coil printed on a flexible substrate with a 90° bend, according to certain embodiments;

FIG. 8B shows a sensor structure comprised of two parts including a horizontal PCB with a horizontal portion of a coil, and a vertical PCB with a horizontal portion of a coil, according to certain embodiments;

FIG. 9A shows a key structure with a dual orthogonal sensor structure, according to certain embodiments;

FIG. 9B shows a key structure with a dual orthogonal sensor structure, according to certain embodiments;

FIG. 9C shows a key structure with a dual orthogonal sensor structure, according to certain embodiments;

FIG. 9D shows a key structure with a dual orthogonal sensor structure, according to certain embodiments;

FIG. 9E shows a key structure with a dual orthogonal sensor structure, according to certain embodiments;

FIG. 9F shows a key structure with a dual orthogonal sensor structure, according to certain embodiments;

FIG. 10A is a plot showing sensitivity characteristics for a sensor when a target moves both directly towards the sensor and sideways at a fixed distance from the sensor, according to certain embodiments;

FIG. 10B shows signal strength versus target distance as a target moves along the X-axis directly toward the sensor, according to certain embodiments;

FIG. 10C shows signal strength versus target distance as a target moves along the Y-axis at a fixed orthogonal distance from the sensor, according to certain embodiments;

FIG. 10D shows a linear region for a full size mechanical keyboard switch with 4 mm travel range, according to certain embodiments;

FIG. 11A shows a key structure with non-linear characteristics at a top portion of its travel range;

FIG. 11B shows a key structure with linear characteristics at a top portion of its travel range, according to certain embodiments;

FIG. 11C shows a key structure at a bottom portion of its travel range;

FIGS. 12A and 12B show the front and back sides of a vertically-oriented sensor with a fixed biasing conductive target coupled thereto, respectively, according to certain embodiments;

FIGS. 13A-13C show aspects of a key structure that can detect both travel and force using a single vertically oriented antenna, according to certain embodiments;

FIGS. 13D-13F how aspects of another key structure that can detect both travel and fore using a single vertically oriented antenna, according to certain embodiments;

FIG. 14A-14G show several novel key structures, according to certain embodiments; and

FIG. 15 is a simplified flow chart showing aspects of a method for travel and force sensing in a key structure with a force analog switch architecture, according to certain embodiments.

Throughout the drawings, it should be noted that like reference numbers are typically used to depict the same or similar elements, features, and structures.

### DETAILED DESCRIPTION

Aspects of the present disclosure relate generally to computer peripheral devices, and more particularly to keyed input devices (e.g., keyboards), according to certain embodiments.

In the following description, various examples of force inductive and analog computer peripheral devices are described. For the purpose of explanation, specific configurations and details are set forth to provide a thorough understanding of the embodiments. However, it will be apparent to one skilled in the art that certain embodiments may be practiced or implemented without every detail disclosed. Furthermore, well-known features may be omitted or simplified to prevent any obfuscation of the novel features described herein.

The following high-level summary is intended to provide a basic understanding of some of the novel innovations depicted in the figures and presented in the corresponding descriptions provided below. Aspects of the invention relate to force-sensing integration in force analog mechanical keyboards. Analog keyboards, as described herein, can provide very accurate detection of a user pressing or releasing a key on the order of 0.1 mm increments. This feature can be referred to as a “rapid trigger” and is often used by gamers to gain a competitive edge. In other contemporary designs (not including the novel design described herein), analog keyboards often have two main limitations: speed and range. Speed can be intrinsically limited by the inertia of the moving parts of the switch (e.g., plunger and keycap) and the momentum of the user's finger. With range, contemporary analog switches are typically only able to detect the position/travel of its plunger. The human finger is not very accurate at precisely displacing or maintaining the position of freely moving objects, mostly due to the lack of proper feedback from the object and finger tremor. Some aspects of the invention provide a hybrid approach with switches that can detect the force applied on the plunger once it reaches the end of the travel (e.g., the bottom-out force) and basically extends the sensing range to a “force region” where the sensing speed is no longer limited by the inertia (as there is little to no motion). Thus, the greater force applied on the finger provides much better feedback to the user and substantially mitigates tremors to provide more accurate control. The extended range can further be better for multi-threshold inputs (e.g., the first threshold in travel region, the second threshold in force region), and, depending on the action linked with the thresholds, it can be a very intuitive way to interact with the computer/application/game. For example, a first threshold associated with a first range of motion (travel region) can control a first action, while a second threshold associated with a second range of motion (e.g., the force region at or near the bottom of the plunger range of motion), can control a second action. In some cases, the thresholds can be fixed or can incorporate hysteresis to allow different thresholds in downward motions (e.g., pressing) versus upward motions (releasing). The following description explores and expressly or implicitly describes a number of different implementations to achieve both travel and force detection, as would be appreciated by one of ordinary skill in the art with the benefit of this disclosure.

It is to be understood that this high-level summary is presented to provide the reader with a baseline understanding of some of the novel aspects of the present disclosure and a roadmap to the details that follow. This high-level summary in no way limits the scope of the various embodiments described throughout the detailed description and each of the figures referenced above are further described below in greater detail and in their proper scope.

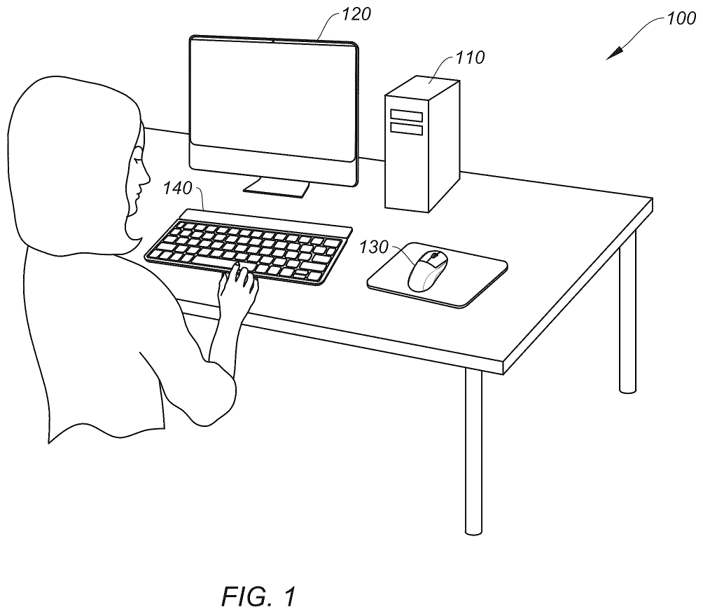

FIG. 1 shows a simplified example of a computer system 100 that can include any of a variety of host computing devices and computer peripheral devices, including computer peripheral devices (e.g., a computer mouse, keyboard, etc.) that can be configured to perform aspects of the various inventive concepts described herein. Computer system 100 can include computer 110, monitor 120, computer mouse 130, and keyboard 140. In some cases, keyboard 140 can be a “qwerty” style keyboard, or any suitable input device (e.g., internet-of-things device, AR/VR controller, remote controller, or the like) with one or more keys that can be configured as analog keys with travel and force detection, as further described throughout this disclosure. For computer system 100, keyboard 140 can be configured to control various aspects of computer 110 and monitor 120, as would be appreciated by one of ordinary skill in the art with the benefit of this disclosure. The monitor 120, computer mouse 130, and keyboard 140 may be referred to generally as “computer peripheral devices” or “input devices.” Computer peripheral devices 120-140 can be communicatively coupled to host computing device 110 and, in some cases, may be coupled to multiple host computing devices. Although many of the examples presented herein utilize analog keys in a keyboard-type computer peripheral device, it would be understood by those of ordinary skill in the art with the benefit of this disclosure that the usage of such structures can be applied to other types of input devices.

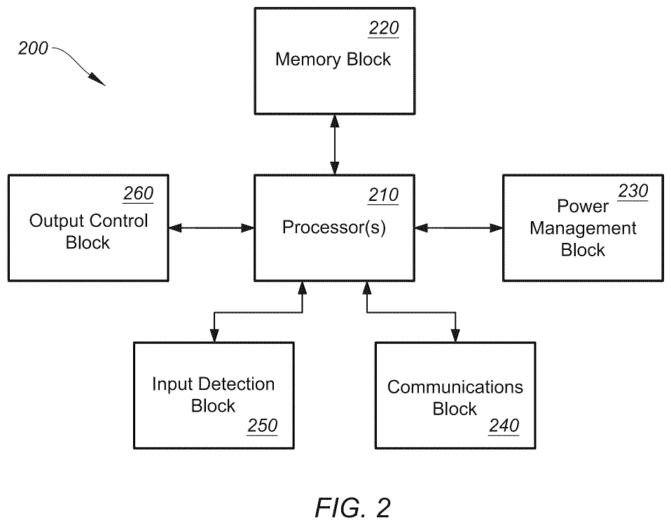

Computer 110 can be any suitable computing device including, but not limited to, a desktop computer, a laptop computer, a tablet or “phablet” computer, a smartphone, a PDA, a wearable device (e.g., smart watches, smart glasses), virtual reality/augmented reality (VR/AR) system, or the like. A host computing device may also be referred to herein as a “host computer,” “host device,” “computing device,” “computer,” or the like, and may include a machine-readable medium (not shown) configured to store computer code, such as driver software, firmware, and the like, where the computer code may be executable by one or more processors of the host computing device(s) (see, e.g., processor(s) 210 of FIG. 2) to control aspects of the host computing device, for instance, via the one or more computer peripheral devices.

FIG. 2 shows a system 200 for operating a computer peripheral device (e.g., computer mouse 130, keyboard 140, etc.), according to certain embodiments. System 200 may be configured to operate any of the computer peripheral devices shown or not shown herein but within the wide purview of the present disclosure. System 200 may include processor(s) 210, a memory 220, a power management system 230, a communication module 240, an input detection module 250, and an output control module 260. Each of the system blocks 220-260 can be in electronic communication with processor(s) 210 (e.g., via a bus system). System 200 may include additional functional blocks that are not shown or discussed to prevent obfuscation of the novel features described herein. System blocks 220-260 (also referred to as “modules”) may be implemented as separate blocks, or alternatively, more than one system block may be implemented in a single block. In the context described herein, system 200 can be incorporated into any computer peripheral devices (e.g., input devices) described or mentioned herein and may be further configured with any of the analog key structures presented herein, as would be appreciated by one of ordinary skill in the art with the benefit of this disclosure.

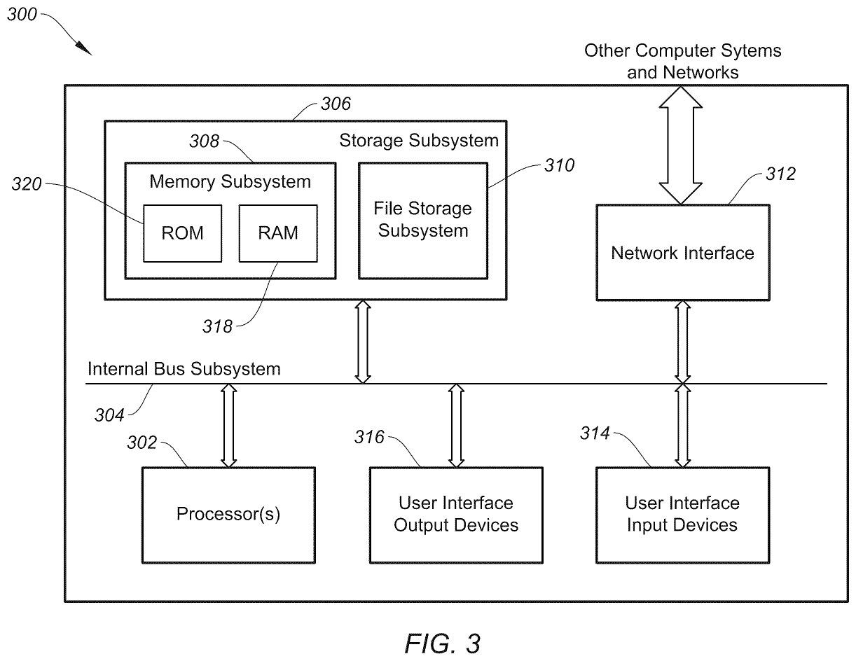

In certain embodiments, processor(s) 210 may include one or more microprocessors and can be configured to control the operation of system 200. Alternatively or additionally, processor(s) 210 may include one or more microcontrollers (MCUs), digital signal processors (DSPs), or the like, with supporting hardware and/or firmware (e.g., memory, programmable I/Os, etc.), and/or software, as would be appreciated by one of ordinary skill in the art. Processor(s) 210 can control some or all aspects of the operation of keyboard 140 (e.g., system blocks 220-260). Alternatively or additionally, some of system blocks 220-260 may include an additional dedicated processor, which may work in conjunction with processor(s) 210. For instance, MCUs, μCs, DSPs, and the like, may be configured in other system blocks of system 200. Communications block 240 may include a local processor, for instance, to control aspects of communication with host computer 110 (e.g., via Bluetooth, Bluetooth LE, RF, IR, hardwire, ZigBee, Z-Wave, Logitech Unifying, or other communication protocol). Processor(s) 210 may be local to the computer peripheral device (e.g., contained therein), may be external to the computer peripheral device (e.g., off-board processing, such as by a corresponding host computing device), or a combination thereof. Processor(s) 210 may perform any of the various functions and methods described and/or covered by this disclosure in conjunction with any other system blocks in system 200. In some implementations, processor 302 of FIG. 3 may work in conjunction with processor(s) 210 to perform some or all of the various methods described throughout this disclosure. In some embodiments, multiple processors may enable increased performance characteristics in system 200 (e.g., speed and bandwidth), however, multiple processors are not required, nor necessarily germane to the novelty of the embodiments described herein. One of ordinary skill in the art would understand the many variations, modifications, and alternative embodiments that are possible.

Memory block (“memory”) 220 can store one or more software programs to be executed by one or more processors (e.g., processor(s) 210). It should be understood that “software” can refer to sequences of instructions that, when executed by processing unit(s) (e.g., processors, processing devices, etc.), cause system 200 to perform certain operations of software programs. The instructions can be stored as firmware residing in read-only memory (ROM), and/or applications stored in media storage that can be read into memory for execution by processing devices (e.g., processor(s) 210). Software can be implemented as a single program or a collection of separate programs and can be stored in non-volatile storage and copied in whole or in part to volatile working memory during program execution. In some embodiments, memory 220 may store data corresponding to inputs on the computer peripheral device, such as a detected movement of the computer peripheral device, a sensor (e.g., optical sensor, accelerometer, etc.), activation of one or more input elements (e.g., buttons, sliders, touch-sensitive regions, etc.), or the like. Stored data may be aggregated and sent via reports to a host computing device.

In certain embodiments, memory 220 can store the various data described throughout this disclosure. Memory 220 can be used to store any suitable data to perform any function described herein and as would be appreciated by one of ordinary skill in the art with the benefit of this disclosure. Memory 220 can be referred to as a storage system or storage subsystem and can store one or more software programs to be executed by processors (e.g., in processor(s) 210). It should be understood that “software” can refer to sequences of instructions that, when executed by processing unit(s) (e.g., processors, processing devices, etc.), cause system 200 to perform certain operations of software programs. The instructions can be stored as firmware residing in read-only memory (ROM) and/or applications stored in media storage that can be read into memory for processing by processing devices. Software can be implemented as a single program or a collection of separate programs and can be stored in non-volatile storage and copied in whole or in part to volatile working memory during program execution. From a storage subsystem, processing devices can retrieve program instructions to execute various operations (e.g., software-controlled switches, etc.) as described herein.

Power management system 230 can be configured to manage power distribution, recharging, power efficiency, and the like. In some embodiments, power management system 230 can include a battery (not shown), a Universal Serial Bus (USB)-based recharging system for the battery (not shown), and power management devices (e.g., voltage regulators—not shown), and a power grid within system 200 to provide power to each subsystem (e.g., communications block 240, etc.). In certain embodiments, the functions provided by power management system 230 may be incorporated into processor(s) 210. Alternatively, some embodiments may not include a dedicated power management block. For example, functional aspects of power management block 240 may be subsumed by another block (e.g., processor(s) 210) or in combination therewith. The power source can be a replaceable battery, a rechargeable energy storage device (e.g., super capacitor, Lithium Polymer Battery, NiMH, NiCd), or a corded power supply. The recharging system can be an additional cable (specific for the recharging purpose), or it can use a USB connection to recharge the battery.

Communication system 240 can be configured to enable wireless communication with a corresponding host computing device (e.g., 110), or other devices and/or computer peripherals, according to certain embodiments. Communication system 240 can be configured to provide radiofrequency (RF), Near-Field Communication (NFC), Bluetooth®, Logitech proprietary communication protocol (e.g., Unifying, Gaming Lightspeed, or others), infra-red (IR), ZigBee®, Z-Wave, or other suitable communication technology to communicate with other computing devices and/or peripheral devices. System 200 may optionally comprise a hardwired connection to the corresponding host computing device. For example, computer peripheral device 140 can be configured to receive a USB, FireWire®, Thunderbolt®, or other universal-type cables to enable bi-directional electronic communication with the corresponding host computing device or other external devices. Some embodiments may utilize different types of cables or connection protocol standards to establish hardwired communication with other entities. In some aspects, communication ports (e.g., USB), power ports, etc., may be considered as part of other blocks described herein (e.g., input detection module 250, output control module 260, etc.). In some aspects, communication system 240 can send reports generated by the processor(s) 210 (e.g., HID data, streaming or aggregated data, etc.) to a host computing device. In some cases, the reports can be generated by the processor(s) only, in conjunction with the processor(s), or other entity in system 200. Communication system 240 may incorporate one or more antennas, oscillators, etc., and may operate at any suitable frequency band (e.g., 2.4 GHZ), etc. One of ordinary skill in the art with the benefit of this disclosure would appreciate the many modifications, variations, and alternative embodiments thereof.

Input detection module 250 can control the detection of a user-interaction with input elements on an input device. For instance, input detection module 250 can detect user inputs from motion sensors, keys, or buttons (e.g., depressible elements), roller wheels, scroll wheels, track balls, touch pads (e.g., one and/or two-dimensional touch sensitive touch pads), click wheels, dials, keypads, microphones, GUIs, touch-sensitive GUIs, proximity sensors (e.g., IR, thermal, Hall effect, inductive sensing, etc.), an image sensor based detection such as gesture detection (e.g., via webcam), audio based detection such as voice input (e.g., via microphone), or the like, as would be appreciated by one of ordinary skill in the art with the benefit of this disclosure. Alternatively, the functions of input detection module 250 or subset thereof can be subsumed by processor(s) 210, or in combination therewith.

In some embodiments, input detection module 250 can detect a touch or touch gesture on one or more touch sensitive surfaces on keyboard 140. Input detection block 250 can include one or more touch sensitive surfaces or touch sensors. Touch sensors generally comprise sensing elements suitable to detect a signal such as direct contact, electromagnetic or electrostatic fields, or a beam of electromagnetic radiation. Touch sensors can typically detect changes in a received signal, the presence of a signal, or the absence of a signal. A touch sensor may include a source for emitting the detected signal, or the signal may be generated by a secondary source. Touch sensors may be configured to detect the presence of an object at a distance from a reference zone or point (e.g., <5 mm), contact with a reference zone or point, or a combination thereof. Certain embodiments of computer peripheral device 140 may or may not utilize touch detection or touch sensing capabilities.

Input detection block 250 can include touch and/or proximity sensing capabilities. Some examples of the types of touch/proximity sensors may include, but are not limited to, resistive sensors (e.g., air-gap 4-wire based, based on carbon loaded plastics which have different electrical characteristics depending on the pressure (FSR), interpolated FSR, strain gages, etc.), capacitive sensors (e.g., surface capacitance, self-capacitance, mutual capacitance, etc.), optical sensors (e.g., light barrier type (default open or closed), infrared light barriers matrix, laser based diode coupled with photo-detectors that could measure the time of flight of the light path, etc.), acoustic sensors (e.g., piezo-buzzer coupled with microphones to detect the modification of a wave propagation pattern related to touch points, etc.), inductive sensors, magnetic sensors (e.g., Hall Effect, etc.), or the like.

Input detection module 250 may include a movement tracking sub-block that can be configured to detect a relative displacement (movement tracking) of a computer peripheral device. For example, input detection module 250 optical sensor(s) such as IR LEDs and an imaging array of photodiodes to detect the movement of a computer peripheral device relative to an underlying surface. A computer peripheral device may optionally include movement tracking hardware that utilizes coherent (laser) light. Movement tracking can provide positional data (e.g., delta X and delta Y data from the last sampling) or lift detection data. For example, an optical sensor can detect when a user lifts the computer peripheral device (e.g., computer mouse 130) off an underlying surface (also referred to as a “work surface”) and can send that data to processor(s) 210 for further processing. In some embodiments, processor(s) 210, the movement tracking block (which may include an additional dedicated processor), or a combination thereof, as would be appreciated by one of ordinary skill in the art with the benefit of this disclosure.

In certain embodiments, accelerometers can be used for movement detection. Accelerometers can be electromechanical devices (e.g., micro-electromechanical systems (MEMS) devices) configured to measure acceleration forces (e.g., static and dynamic forces). One or more accelerometers can be used to detect three-dimensional (3D) positioning. For example, 3D tracking can utilize a three-axis accelerometer or two two-axis accelerometers (e.g., in a “3D air mouse,” HMD, or another device). Accelerometers can further determine if the computer peripheral device has been lifted off an underlying surface and can provide movement data that may include the velocity, physical orientation, and acceleration of a computer peripheral device. In some embodiments, gyroscope(s) can be used in lieu of or in conjunction with accelerometer(s) to determine movement or input device orientation.

In some embodiments, input detection block 250 can control aspects of one or more sensing elements, as described herein. For example, input detection block 250 can control a sensing element including a first sensing section configured to detect the movement of a depressible plunger (e.g., with a key cap) along the first range of motion and generate corresponding first data and a second sensing section configured to detect movement of the depressible plunger along the second range of motion and generate corresponding second data. In such cases, processor(s) 210 may be configured to determine a position of the plunger (e.g., target coupled to the plunger) along the first range of motion based on the first data and determine a force produced by the plunger on the dampening element, while the plunger moves along the second range of motion, based on the second data, as further described below.

In some embodiments, output control module 260 can control various outputs for a corresponding computer peripheral device. For instance, output control module 260 may control a number of visual output elements (e.g., LEDs, LCD or LED screens/keys), displays, audio outputs (e.g., speakers), haptic output systems, or the like. One of ordinary skill in the art with the benefit of this disclosure would appreciate the many modifications, variations, and alternative embodiments thereof.

Although certain systems may not be expressly discussed, they should be considered as part of system 200, as would be understood by one of ordinary skill in the art. For example, system 200 may include a bus subsystem to transfer power and/or data to and from the different systems therein. It should be appreciated that system 200 is illustrative and that variations and modifications are possible. System 200 can have other capabilities not specifically described herein. Further, while system 200 is described with reference to particular blocks, it is to be understood that these blocks are defined for convenience of description and are not intended to imply a particular physical arrangement of component parts. Further, the blocks need not correspond to physically distinct components. Blocks can be configured to perform various operations (e.g., by programming a processor or providing appropriate control circuitry) and various blocks might or might not be reconfigurable depending on how the initial configuration is obtained.

Embodiments of the present invention can be realized in a variety of apparatuses including electronic devices (e.g., computer peripheral devices) implemented using any combination of circuitry and software. Furthermore, aspects and/or portions of system 200 may be combined with or operated by other subsystems as required by design. For example, input detection module 250 and/or memory 220 may operate within processor(s) 210 instead of functioning as separate entities. In addition, the inventive concepts described herein can also be applied to any electronic device. Further, system 200 can be applied to any of the computer peripheral devices described in the embodiments herein, whether explicitly, referentially, or tacitly described (e.g., would have been known to apply to a particular computer peripheral device by one of ordinary skill in the art). The foregoing embodiments are not intended to be limiting and those of ordinary skill in the art with the benefit of this disclosure would appreciate the myriad applications and possibilities.

FIG. 3 is a simplified block diagram of a host computing device 300, according to certain embodiments. Host computing device 300 can implement some or all functions, behaviors, and/or capabilities described herein that would use electronic storage or processing, as well as other functions, behaviors, or capabilities not expressly described. Host computing device 300 can include a processing subsystem (processor(s)) 302, a storage subsystem 306, user interfaces 314, 316, and a communication interface 312. Computing device 300 can also include other components (not explicitly shown) such as a battery, power controllers, and other components operable to provide various enhanced capabilities. In various embodiments, host computing device 300 can be implemented in any suitable computing device, such as a desktop or laptop computer (e.g., desktop 110), mobile device (e.g., tablet computer, smart phone, mobile phone), wearable device, media device, or the like, or in peripheral devices (e.g., keyboards, etc.) in certain implementations.

Processor(s) 302 can include MCU(s), micro-processors, application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, or electronic units designed to perform a function, portions of functions, or a combination of methods, functions, etc., described throughout this disclosure.

Storage subsystem 306 can be implemented using a local storage and/or removable storage medium, e.g., using disk, flash memory (e.g., secure digital card, universal serial bus flash drive), or any other non-transitory storage medium, or a combination of media, and can include volatile and/or non-volatile storage media. Local storage can include a memory subsystem 308 including random access memory (RAM) 318 such as dynamic RAM (DRAM), static RAM (SRAM), synchronous dynamic RAM (e.g., DDR), or battery backed-up RAM or read-only memory (ROM) 320, or a file storage subsystem 310 that may include one or more code modules. In some embodiments, storage subsystem 306 can store one or more applications and/or operating system programs to be executed by processing subsystem 302, including programs to implement some or all operations described above that would be performed using a computer. For example, storage subsystem 306 can store one or more code modules for implementing one or more method steps described herein.

A firmware and/or software implementation may be implemented with modules (e.g., procedures, functions, and so on). A machine-readable medium tangibly embodying instructions may be used in implementing the methodologies described herein. Code modules (e.g., instructions stored in memory) may be implemented within a processor or external to the processor. As used herein, the term “memory” refers to a type of long term, short term, volatile, nonvolatile, or other storage medium, and is not to be limited to any particular type of memory or number of memories, or type of media upon which memory is stored.

Moreover, the term “storage medium” or “storage device” may represent one or more memories for storing data, including read only memory (ROM), RAM, magnetic RAM, core memory, magnetic disk storage mediums, optical storage mediums, flash memory devices and/or other machine-readable mediums for storing information. The term “machine-readable medium” includes, but is not limited to, portable or fixed storage devices, optical storage devices, wireless channels, and/or various other storage mediums capable of storing instruction(s) and/or data.

Furthermore, embodiments may be implemented by hardware, software, scripting languages, firmware, middleware, microcode, hardware description languages, and/or any combination thereof. When implemented in software, firmware, middleware, scripting language, and/or microcode, program code or code segments to perform tasks may be stored in a machine-readable medium such as a storage medium. A code segment (e.g., code module) or machine-executable instruction may represent a procedure, a function, a subprogram, a program, a routine, a subroutine, a module, a software package, a script, a class, or a combination of instructions, data structures, and/or program statements. A code segment may be coupled to another code segment or a hardware circuit by passing and/or receiving information, data, arguments, parameters, and/or memory contents. Information, arguments, parameters, data, etc. may be passed, forwarded, or transmitted by suitable means including memory sharing, message passing, token passing, network transmission, etc. These descriptions of software, firmware, storage mediums, etc., apply to systems 200 and 300, as well as any other implementations within the wide purview of the present disclosure. In some embodiments, aspects of the invention (e.g., surface classification) may be performed by software stored in storage subsystem 306, stored in memory 220 of a computer peripheral device, or both. One of ordinary skill in the art with the benefit of this disclosure would appreciate the many modifications, variations, and alternative embodiments thereof.

Implementation of the techniques, blocks, steps, and means described throughout the present disclosure may be done in various ways. For example, these techniques, blocks, steps, and means may be implemented in hardware, software, or a combination thereof. For a hardware implementation, the processing units may be implemented within one or more ASICs, DSPs, DSPDs, PLDs, FPGAs, processors, controllers, micro-controllers, microprocessors, other electronic units designed to perform the functions described above, and/or a combination thereof.

Each code module may comprise sets of instructions (codes) embodied on a computer-readable medium that directs a processor of a host computing device 110 to perform corresponding actions. The instructions may be configured to run in sequential order, in parallel (such as under different processing threads), or in a combination thereof. After loading a code module on a general-purpose computer system, the general-purpose computer is transformed into a special-purpose computer system.

Computer programs incorporating various features described herein (e.g., in one or more code modules) may be encoded and stored on various computer readable storage media. Computer readable media encoded with the program code may be packaged with a compatible electronic device, or the program code may be provided separately from electronic devices (e.g., via Internet download or as a separately packaged computer readable storage medium). Storage subsystem 306 can also store information useful for establishing network connections using the communication interface 312.

Computer system 300 may include user interface input devices 314 elements (e.g., touch pad, touch screen, scroll wheel, click wheel, dial, button, switch, keypad, microphone, etc.), as well as user interface output devices 316 (e.g., video screen, indicator lights, speakers, headphone jacks, virtual- or augmented-reality display, etc.), together with supporting electronics (e.g., digital to analog or analog to digital converters, signal processors, etc.). A user can operate input devices of user interface 314 to invoke the functionality of computing device 300 and can view and/or hear output from computing device 300 via output devices of user interface 316.

Processing subsystem 302 can be implemented as one or more processors (e.g., integrated circuits, one or more single core or multi core microprocessors, microcontrollers, central processing unit, graphics processing unit, etc.). In operation, processing subsystem 302 can control the operation of computing device 300. In some embodiments, processing subsystem 302 can execute a variety of programs in response to program code and can maintain multiple concurrently executing programs or processes. At a given time, some or all of a program code to be executed can reside in processing subsystem 302 and/or in storage media, such as storage subsystem 304. Through programming, processing subsystem 302 can provide various functionality for computing device 300. Processing subsystem 302 can also execute other programs to control other functions of computing device 300, including programs that may be stored in storage subsystem 304.

Communication interface (also referred to as network interface) 312 can provide voice and/or data communication capability for computing device 300. In some embodiments, communication interface 312 can include radio frequency (RF) transceiver components for accessing wireless data networks (e.g., Wi-Fi network; 3G, 4G/LTE, 5G; etc.), mobile communication technologies, components for short range wireless communication (e.g., using Bluetooth communication standards, NFC, etc.), other components, or combinations of technologies. In some embodiments, communication interface 312 can provide wired connectivity (e.g., universal serial bus (USB), Ethernet, universal asynchronous receiver/transmitter, etc.) in addition to, or in lieu of, a wireless interface. Communication interface 312 can be implemented using a combination of hardware (e.g., driver circuits, antennas, modulators/demodulators, encoders/decoders, and other analog and/or digital signal processing circuits) and software components. In some embodiments, communication interface 312 can support multiple communication channels concurrently.

User interface input devices 314 may include any suitable computer peripheral device (e.g., computer mouse, keyboard, gaming controller, remote control, stylus device, etc.), as would be appreciated by one of ordinary skill in the art with the benefit of this disclosure. User interface output devices 316 can include display devices (e.g., a monitor, television, projection device, etc.), audio devices (e.g., speakers, microphones), haptic devices, etc. Note that user interface input and output devices are shown to be a part of system 300 as an integrated system. In some cases, such as in laptop computers, this may be the case as keyboards and input elements as well as display and output elements are integrated on the same host computing device. In some cases, the input and output devices may be separate from system 300, as shown in FIG. 1. One of ordinary skill in the art with the benefit of this disclosure would appreciate the many modifications, variations, and alternative embodiments thereof.

It will be appreciated that computing device 300 is illustrative and that variations and modifications are possible. A host computing device can have various functionality not specifically described (e.g., voice communication via cellular telephone networks) and can include components appropriate to such functionality. While the computing device 300 is described with reference to particular blocks, it is to be understood that these blocks are defined for convenience of description and are not intended to imply a particular physical arrangement of component parts. For example, processing subsystem 302, storage subsystem 306, user interfaces 314, 316, and communications interface 312 can be in one device or distributed among multiple devices. Further, the blocks need not correspond to physically distinct components. Blocks can be configured to perform various operations (e.g., by programming a processor or providing appropriate control circuitry) and various blocks might or might not be reconfigurable depending on how an initial configuration is obtained. Embodiments of the present invention can be realized in a variety of apparatus including electronic devices implemented using a combination of circuitry and software. Host computing devices or even peripheral devices described herein can be implemented using system 300.

### Force Sensing Integration in Analog Mechanical Keyboards

As described above, aspects of the invention incorporate force-sensing integration in analog mechanical keyboards, such that a key structure that can detect a force applied on a key plunger once it is at or near the end of the travel range, which operates to extend the sensing range to a “force region” where the sensing speed is no longer limited by the inertia and the greater force applied on the finger provides much better feedback to the user and substantially mitigates tremor to provide more accurate control. The extended range can further be better for multi-threshold inputs (e.g., first threshold in travel region, second threshold in force region), and depending on the action linked with the thresholds it can be a very intuitive way to interact with the computer/application/game. For example, a first threshold associated with a first range of motion (travel region) can control a first action, while a second threshold associated with a second range of motion (e.g., the force region at or near the bottom of the plunger range of motion), can control a second action. In some cases, the thresholds can be fixed or can incorporate hysteresis to allow different thresholds in downward motions (e.g., pressing) versus upward motions (releasing). Note that while there is benefit during the down motion as highlighted above, there are also benefits on the up motion, as this approach allows detection of an intention of the user to release the key while it is still fully depressed because the force applied on it is being released.

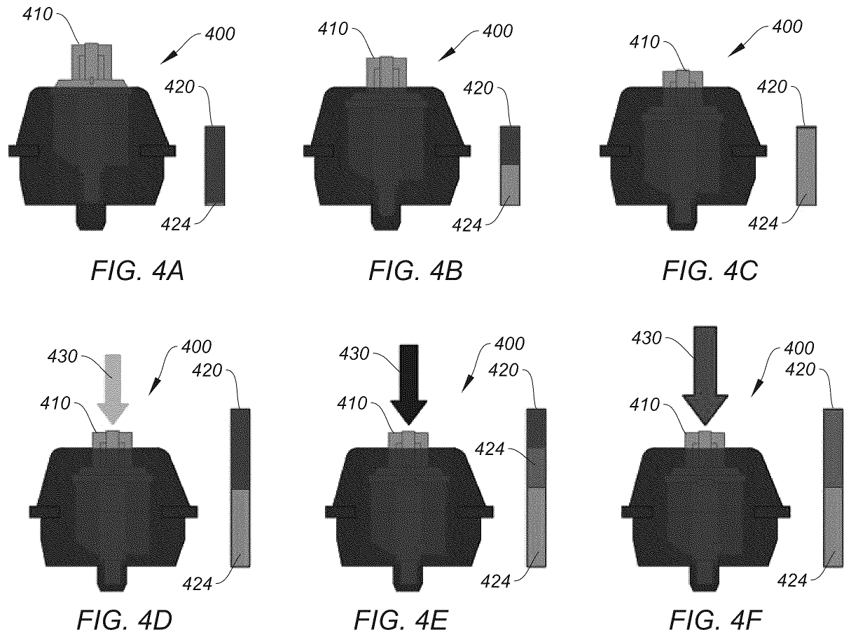

FIGS. 4A-4F show a key press sequence for a key structure 400 with position and force sensing capabilities, according to certain embodiments. Travel/force meter 420 shows how much plunger 410 travels over a combination of a first range of motion 422 and a second range of motion 424 when plunger 410 is depressed. The second range of motion 424 may begin after and be colinear with the first range of motion. Typically, the second range of motion 424 includes motion when plunger 410 comes into contact with and compresses a dampening element. In other words, the first range of motion spans from 0 mm travel (non-depressed key/plunger) to approximately 3-4 mm (other ranges are possible) when the plunger comes into contact with a depressible element. The plunger can continue to be depressed over a second range of motion (e.g., <1 mm), however with resistance from the depressible element, wherein the user can intuitively use to fine tune an amount of force being applied to the key and plunger. In FIG. 4A, plunger 410 of key structure 400 is unpressed and travel/force meter 420 shows that no plunger travel has occurred. In FIG. 4B, plunger 410 is pressed by about 50% over the first range of motion 422, as reflected by travel/force meter 420. In FIG. 4C, plunger 410 is pressed by nearly 95% or more over the first range of motion, as shown in travel/force meter 420. In FIG. 4D, plunger 410 reaches the end of the first range of motion, comes into contact with a dampening element (not shown), and enters the second range of motion. There is a relatively small amount of additional displacement (e.g., <0.5 mm) however the amount of additional user force 430 to continue downward movement and overcome the resistance presented by the dampening element increases. In some cases a switch may have an actuation force (a force required for a MAKE command to be sent to the computer and when the “haptic” point is felt by the user) of approximately 50 to 60 gf. In some aspects, near the end of the travel a switch is generally between 60 and 90 gf. The force region is typically (though not necessarily) between the 60-90 gf and roughly 250 gf. In FIG. 4E, plunger 410 is pressed by about 50% over the second range of motion, wherein the additional displacement is less than 1 mm and the force 430 has increased substantially. In FIG. 4F, plunger 410 is depressed by about 100% over the second range of motion, reaching maximum deflection with a corresponding substantially increased force 430.

### Combined Analog Force Sensing and Analog Travel Sensing

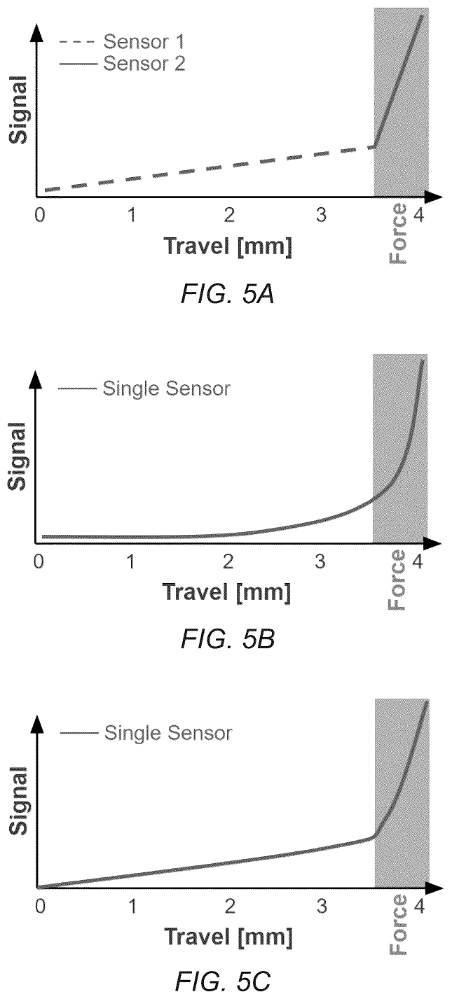

A relatively simple way of implementing force sensing on an analog keyboard is to implement a dedicated force sensor and a separate position sensor under each key in a dual sensor configuration. In such embodiments, each sensor can be tuned to provide the best quality signal (e.g., signal strength and linearity) for their dedicated working range. FIG. 5A is a plot that shows an idealized dual sensor configuration to achieve two linear sense curves, according to certain embodiments. In this case, a first sensor is configured to detect key travel when the key/plunger is moved from 0-3.5 mm, and a second sensor is configured to detect a force during key displacements of approximately 3.5 mm to maximum deflection (e.g., 4 mm), according to certain embodiments. Note that other suitable ranges are possible, as would be appreciated by one of ordinary skill in the art with the benefit of this disclosure. Each sensor can be tuned for optimal performance over their respective ranges. However, dual sensor designs can have many drawbacks including high component cost, increased complexity and footprint on the circuit board, increased processing power, sustainability, and more. A better solution is to use the same single sensor for both the travel and force regions. Since the displacement is greatly reduced in the force region, the system should be designed in a manner that provides a relatively high sensitivity during the force phase, and a lower sensitivity during the travel phase. A linear sensitivity in the travel region is important to accurately measure key travel.

Many types of sensing principles (e.g., inductive, magnetic, capacitive) will generate a signal that diverges (e.g., due to high sensitivity) when their target (respectively a conductor, magnet, or a dielectric coupled to or integrated with the plunger) moves to a very close proximity to the sensor. By ensuring that the target is in close proximity with the sensor during the force phase, a highly sensitive signal in that area can be achieved using the same sensor that is used over the travel range. FIG. 5B is a plot that shows a key structure with a single sensor architecture with diverging sensitivity characteristics, according to certain embodiments. As shown, these types of sensing architectures can be highly non-linear and can have poor sensing performance as the target gets further away. For example, in FIG. 5B there is key travel over at least half of the travel range (e.g., 2 mm) before there is any substantial divergence in sensitivity. In other words, nearly 2 mm of travel occurs before there is any discernable change in signal, which would make it difficult for a user to intuitively depress the key plunger to achieve a particular analog output based on displacement because of the non-linearity of the signal over the travel range. In some embodiments, the raw sensor signal can be improved with better sensitivity and linearization in both the travel phase (first range of motion) and force phase (second range of motion) by applying some novel modifications including: (1) mechanical sensor-target distance reduction; (2) sensor signal biasing; and (3) modified motion of the target relative to the sensor. FIG. 5C is a plot that shows a key structure with a single sensor architecture with modifications that linearize travel sensing, according to certain embodiments. For the purposes of instructive guidance, the graphs are normalized, such that 100% signal corresponds to a maximum Y value.

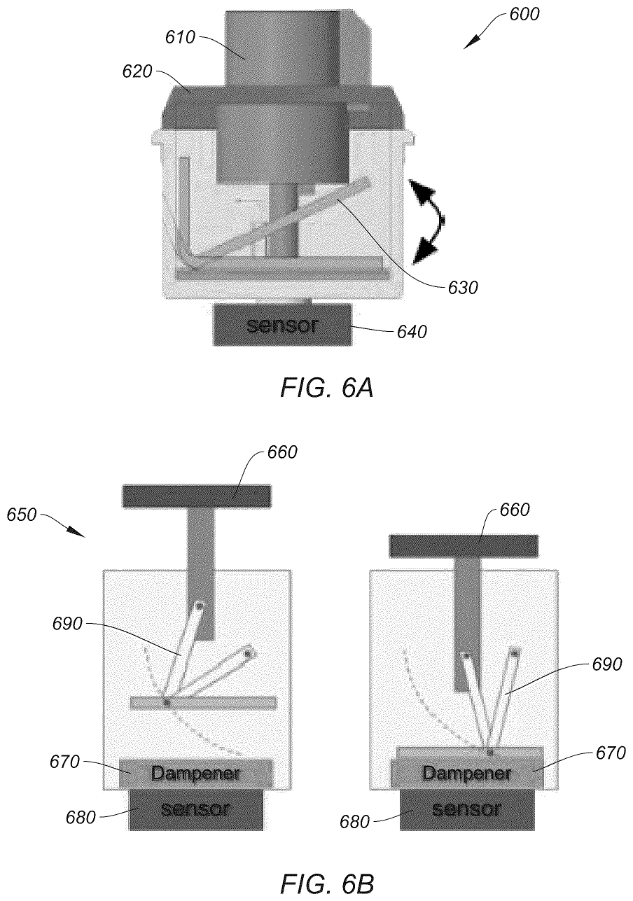

In some embodiments, mechanical sensor-target distance reduction may be achieved by keeping the target close enough to the sensor during the full plunger motion, which can result in improved sensitivity over the full range of motion. FIG. 6A shows a key structure 600 with improved sensitivity due to a moveable drawbridge platform 630 and a target structure that moves with a plunger 610 as it is depressed, according to certain embodiments. Key structure 600 further includes a sensor 640 and a dampening element 620. In the first position (button unpressed), platform 630 is biased and angled upwards (e.g., 30 degrees). As a user depresses plunger 610, platform 630 is pushed down until flat. Such embodiments have an average detected position of the target reduced (e.g., halved), such that the medium point is closer to the sensor even when there is no plunger displacement. For example, instead of a 4 mm distance at no displacement, the measurement starts at 2 mm due to the platform 630 being initially closer to the sensor. Thus, sensing begins at a linearized portion (see, e.g., FIG. 5B) for better tracking, but does not linearize the slope of the sensing curve.

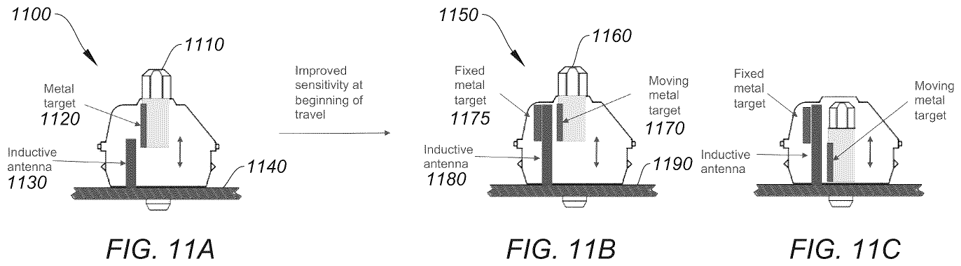

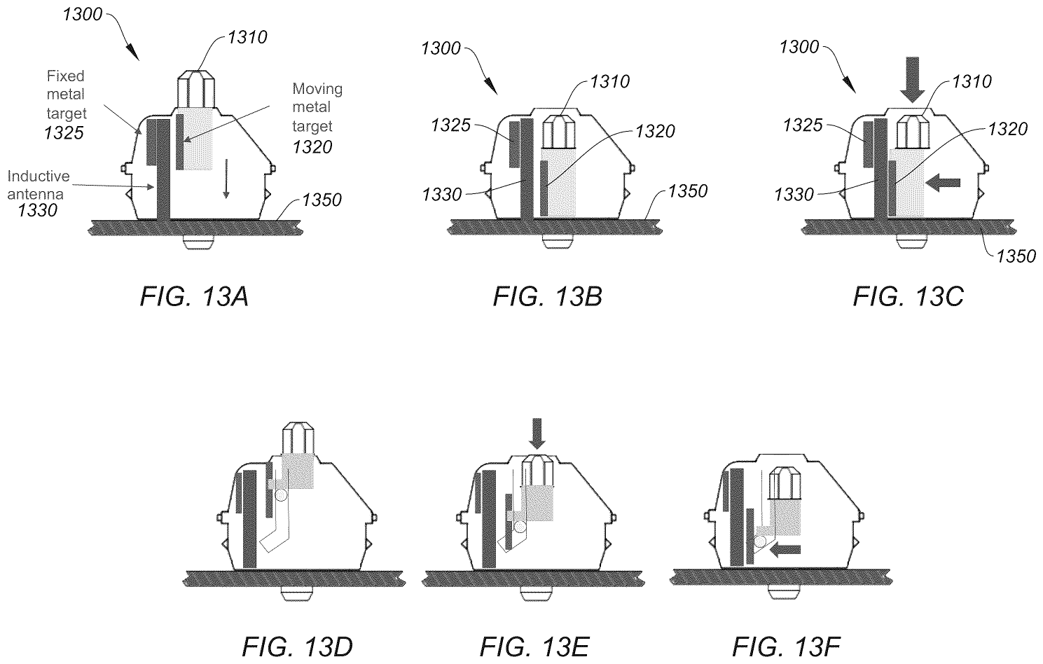

In certain embodiments, sensor signal biasing can be achieved by adding a constant or static target in the system, which may operate to shift sensing to a more sensitive region where small variations in travel have improved sensor sensitivity, as further described below and shown with respect to at least FIGS. 11B, 11C, 13A-C, and 15.

In certain embodiments, changing the way the target is being moved relative to the sensor can improve linearization of the sensor signal over the range of motion. For example, FIG. 6B shows a key structure 650 with improved sensitivity due to a moveable drawbridge platform 690 and a target structure that moves with a plunger 660 as it is depressed, according to certain embodiments. Key structure 650 further includes a sensor 680 and dampening element 670. Note that the target is moved up against dampening element 670 near the bottom of the range of motion of plunger 660, such that platform 690 initially moves quickly as the plunger moves down but then slows, which inversely tracks the sensor curve and cancels some of the non-linearity, making for a mechanical embodiment that can improve sensing linearity over the full range of motion of plunger 660. Note that the key press range can vary. The examples provided herein show roughly 3.5 mm to 4 mm of total travel. Some embodiments may have shorter or longer ranges of motion, including shorter or longer ranges of motion over the force sensing range (second range of motion). Further, many of the embodiments presented herein utilize magnetic sensing. Any suitable detection scheme can be used including inductive (e.g., inductive sensor and target with conductive material), capacitive (e.g., electrode sensor and geometric element), optical (e.g., shutter based or reflective), and magnetic (e.g., Hall Effect sensing, and similar sensing methodologies (e.g., TMR, GMR, etc.). One of ordinary skill in the art with the benefit of this disclosure would appreciate the many modifications, variations, and alternative embodiments thereof.

### Orthogonal Sensing

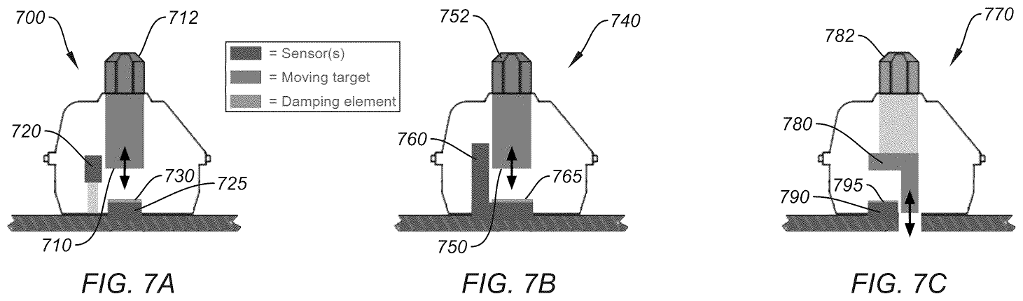

To improve the farther distance travel sense, one can reduce the sensor-target distance by having an elevated vertically mounted sensor (see, e.g., FIGS. 7A-7B) or by having a vertically elongated target that goes through the printed circuit board (see, e.g., FIG. 7C), which may be utilized with full size switches (e.g., 4 mm travel). FIG. 7A shows a key structure 700 and target 710 configured on a plunger 712 with separate orthogonally configured sensors 720, 725, according to certain embodiments. Key structure 700 further includes a dampening element 730. Vertically oriented sensor 720 is closer to the target during travel than horizontally oriented sensor 725 and thus provides better sensitivity over the travel range of motion. The horizontally oriented sensor 725 can be used for force sensing when the target 710 (e.g., coupled to or integrated with the plunger) reaches the bottom of the switch, compresses the dampening element 730, and is in close proximity with the sensor, where the sensing signal can be highly sensitive due to the divergence. The damping element 730 may operate to convert the bottom-out force into a very small displacement of the target. This very small horizontal displacement (e.g., <0.5 mm) can be captured by the horizontally oriented sensor 725 due to its high sensitivity and a force can be indirectly calculated based on the displacement. FIG. 7B shows a key structure 740 and a target 750 configured on a plunger 752 with a single sensor 760 having orthogonally configured sections, according to certain embodiments. Key structure 700 further includes a dampening element 765.

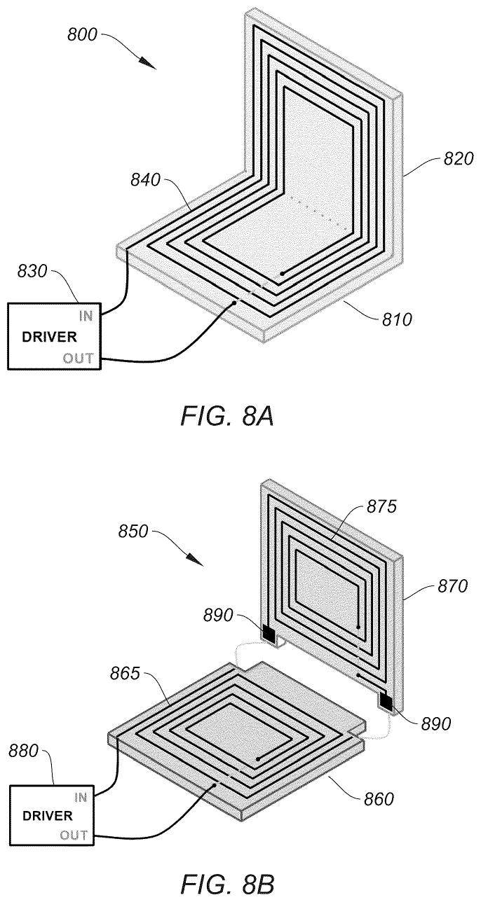

Some examples of a single, orthogonally configured sensor utilizing inductive sensing antennas/coils are presented in FIGS. 8A-8B. FIG. 8A shows a sensor structure 800 with a single coil 840 printed on a flexible substrate with a 90° bend, according to certain embodiments. Coil 840 may be driven by driver circuit 830 and can traverse a horizontally oriented portion 810 of the substrate and a vertically oriented portion 820 of the substrate to achieve good travel and force sensitivity, as described above. FIG. 8B shows a sensor structure 850 comprised of two parts including a horizontal PCB 860 with a horizontal portion of a coil 865, and a vertical PCB 870 with a horizontal portion of a coil 875, according to certain embodiments. The coils 865, 875 are configured in series or parallel via connectors 890 and are driven by driver circuit 880. Alternatively or additionally, other types of sensors (e.g., capacitive) can be used, as would be appreciated by one of ordinary skill in the art with the benefit of this disclosure.

FIG. 7C shows a key structure 770 with a vertically and horizontally elongated target 780, according to certain embodiments. Target 780 passes through the PCB as the plunger 782 is depressed. Key structure 770 further includes dampening element 795 and single horizontally oriented sensor 790. Unlike key structure 850 of FIG. B, the target itself has a horizontally and vertically extended portion, such that the vertically extended portion remains in close proximity to sensor 790 during the travel phase of the key press and the horizontally extended portion comes into contact with dampening element 795 for the small displacement (indirect) force measurement, as described above.

### Embodiments of Dual Orthogonal Sensor Systems

As described above, each key structure can utilize two different sensors to sense travel and force, as shown in FIG. 7A, a single sensor configured in two orthogonal directions, as shown in FIG. 7B and FIGS. 8A-8B, or a modified target and a single sensor, as shown in FIG. 7C. Travel sensing may be based on inductive sensing systems (as previously shown), but can additionally or alternatively be magnetic, capacitive, optical, resistive, or the like, as would be appreciated by one of ordinary skill in the art with the benefit of this disclosure. Force sensing too may be based on inductive sensing systems, but can additionally or alternatively be a magnetic sensor, capacitive sensor, optical sensor, piezo-based sensor, pressure-based sensor, strain gauge sensor, or the like, as would be appreciated by one of ordinary skill in the art with the benefit of this disclosure. Further embodiments with different combinations of sensing systems are described below.

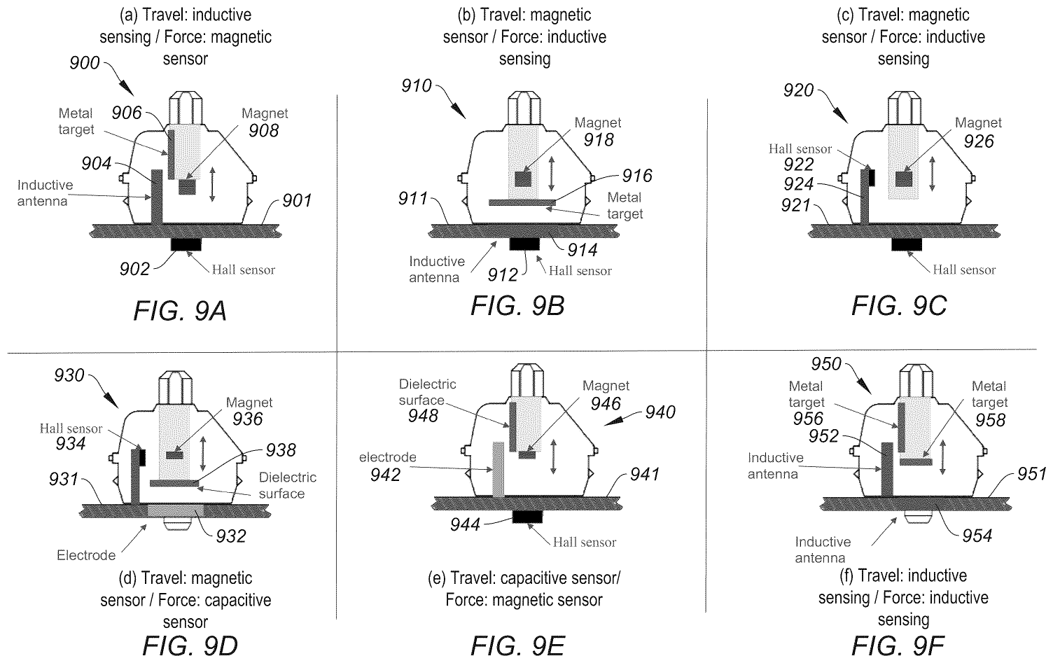

FIG. 9A shows a key structure 900 with a dual orthogonal sensor structure, according to certain embodiments. Key structure 900 includes a printed circuit board (PCB) 901, Hall sensor 902, inductive antenna 904, metal target 906, and magnet 908. Sensor 902 is configured below PCB 901 and in line with the travel path of the plunger and metal target 906. In operation, metal target 906 is detected by antenna 904 during the travel phase of the plunger, and magnet 908 is detected by Hall sensor 902 during the force sensing phase. In some aspects, a dampening element can be included in FIGS. 9A-9F.

FIG. 9B shows a key structure 910 with a dual orthogonal sensor structure, according to certain embodiments. Key structure 910 includes a PCB 911, Hall sensor 912, inductive antenna 914, metal target 916, and magnet 918. Both Hall sensor 912 and inductive antenna 914 are configured below PCB 911 and in line with the travel path of the plunger and metal target 916. In operation, Hall sensor 912 detects magnet 918 during the travel phase of the plunger, while inductive antenna 914 detects metal target 916 during the force phase.

FIG. 9C shows a key structure 920 with a dual orthogonal sensor structure, according to certain embodiments. Key structure 920 includes a first Hall sensor 922 configured under PCB 921 in line with the travel path of the plunger and magnet 926, and a second Hall sensor 924 configured on a vertically extended portion of PCB 921. In operation, the first Hall sensor 922 detects magnet 926 during the travel phase of the plunger, and the second Hall sensor 924 detects the same magnet 926 during the force phase.

FIG. 9D shows a key structure 930 with a dual orthogonal sensor structure, according to certain embodiments. Key structure 930 includes PCB 931, an electrode 932, Hall sensor 934, magnet 936, and dielectric surface 938. Both magnet 936 and dielectric surface 938 (both operating as targets) are coupled to or integrated with the plunger. In operation, Hall sensor 934 detects magnet 936 during the travel phase of the plunger, and electrode 932 detects dielectric surface 938 during the force phase.

FIG. 9E shows a key structure 940 with a dual orthogonal sensor structure, according to certain embodiments. Key structure 940 includes a PCB 941, electrode 942, sensor 944, magnet 946, and dielectric surface 948. Both magnet 946 and dielectric surface 948 (both operating as targets) are coupled to or integrated with the plunger, but in different locations as compared to key structure 930 of FIG. 9D. In operation, electrode 942 detects dielectric surface 948 during the travel phase of the plunger, and Hall sensor 944 detects magnet 946 during the force phase.

FIG. 9F shows a key structure 950 with a dual orthogonal sensor structure, according to certain embodiments. Key structure 950 includes PCB 951, inductive antenna 952, inductive antenna 954, metal target 956, and metal target 958. This embodiment operates similarly to key structure 700 of FIG. 7A, but with two metal targets 956, 958 (instead of one) that are better aligned with their corresponding inductive antennas 952, 954, respectively.

### Embodiments of Vertical-Only Sensing Systems

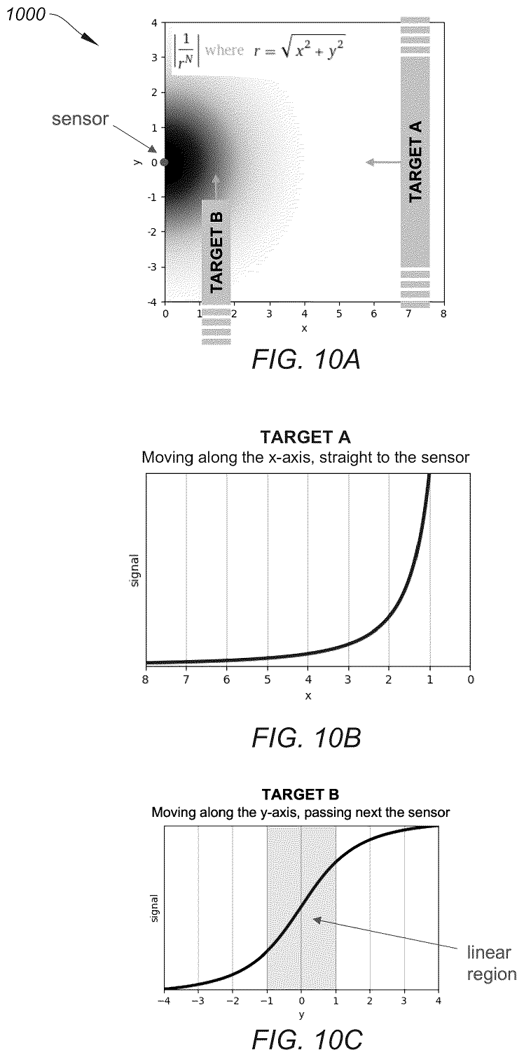

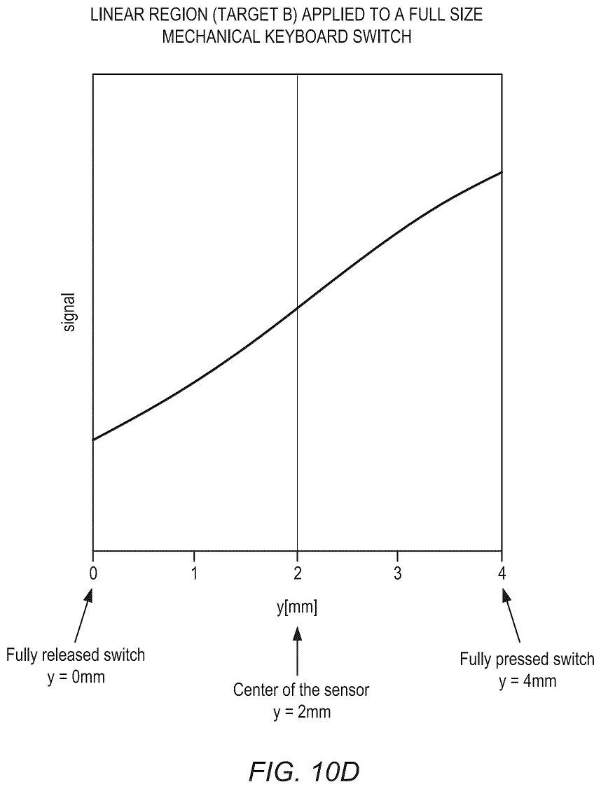

A raw sensor signal can be improved with better sensitivity and linearization in both the travel phase (first range of motion) and force phase (second range of motion) by modifying the motion of a target relative to a sensor, as described above. FIG. 10A is a plot 1000 showing sensitivity characteristics for a sensor when a target moves both directly towards the sensor (Target A) and sideways at a fixed distance from the sensor (Target B), according to certain embodiments. The sensor is located at (0,0) of an X-Y Cartesian coordinate system, where the X-axis defines a distance from the sensor in a first linear direction, and the Y-axis defines a distance from the sensor in a second linear direction orthogonal to the first linear direction. A simplified representation of the strength of the sensor signal can be defined by equation (1):

$$\vert \frac{1}{{r}^{N}} \vert \qquad ( 1 )$$

where r=\sqrt{x²+y²}, r is the radial distance between the sensor and any point on the plane (e.g., in polar coordinates), and N is the decay rate of the sensing sensitivity. In some aspects, the N value can be different depending on the type of sensing used. For instance, if the sensing is performed with an optical implementation, the light intensity “I” as a function of the distance “r” would follow the inverse square law: I∝1/(r\hat{ }2), such that in that case N=2.

FIG. 10B shows signal strength versus target distance as Target A moves along the X-axis directly towards the sensor, accordingly to certain embodiments. For illustrative purposes, the signal is normalized between 0 and 100%, and the signal behavior is similar for magnetic or inductive sensing systems and have a squared relationship with the distance, as noted above. Thus, as Target A moves straight at the sensor from a relatively far distance (e.g., 4-8 mm; non-pressed key/plunger) the signal increases non-linearly at a very slow increasing rate and diverges (increases exponentially) when the target gets relatively close to the sensor (e.g., 1-2 mm; pressed key/plunger). This diverging behavior can be exploited for efficient force analog sensing.

FIG. 10C shows signal strength versus target distance as Target B moves along the Y-axis at a fixed orthogonal distance from the sensor, according to certain embodiments. A linear sensing region results as Target B moves near the center position (0,0) of the sensor, which can be exploited for efficient analog travel sensing, as described above.

In some cases, the first portion of the travel (e.g., 0-2 mm) may still remain non-linear and difficult to track accurately. In some embodiments, the target initial position can start directly at the beginning of the linear region in order to skip the non-linear initial portion of the curve. This may not be a practical solution in some cases as the plunger/target may have a shorter throw (travel length), which may cause a sub-optimal user experience (UX).

In some embodiments, a secondary fixed target can be placed at or near the initial range of travel, which can bias the sensor when the moving target is initially being depressed or at the end of its release. In some implementations, the vertically oriented sensor (e.g., inductive sensing coil) may be configured to be larger than the target (e.g., two times larger), such that the upper portion of the sensor (e.g., within the first 2 mm of travel) is substantially close (e.g., within 1-2 mm) to the fixed target (e.g., a conductor), resulting in a more linearized detection curve (e.g., more similar to FIG. 5C rather than FIG. 5B) over the first portion of travel.

FIG. 11A shows a key structure 1100 with non-linear characteristics at the top portion of its travel range. Key structure 1100 includes a plunger 1110, moving metal target 1120, vertically-oriented sensor (e.g., inductive antenna) 1130, and PCB 1140. Metal target 1120 is coupled to plunger 1110. Sensor 1130 may be operable to perform travel detection with non-linear characteristics, similar to Target B of FIG. 10B, because target 1120 is farther from sensor 1130 at the top portion of its travel range, as shown.

FIG. 11B shows a key structure 1150 with linear characteristics at the top portion of its travel range, according to certain embodiments. Key structure 1150 includes a plunger 1160 and a moving metal target 1170 coupled thereto, vertically-oriented and extended sensor (e.g., inductive antenna) 1180, and a fixed metal target 1175 coupled to a top portion of PCB 1190. Sensor 1180 may perform travel detection with more linearized characteristics because both target 1170 and biasing fixed target 1175 are closer to extended sensor 1180 along the entire travel range, as shown. FIG. 11C shows key structure 1150 at the bottom portion of its travel range.

In some aspects, a Y=0 position may correspond to the center of the sensor on the Y axis. Thus, with a full size keyboard switch with 4 mm travel, the sensor may have its center at a 2 mm distance (e.g., in the middle of the travel). This figure shows that the sensing can be linearized when the target is near the center of the antenna. In some cases, Y=−1 at the top position of the plunger and Y=1 at the bottom of the travel range of the plunger, although other values are possible, as would be appreciated by one of ordinary skill in the art with the benefit of this disclosure. FIG. 10D is a plot showing a linear region (Target B) for a full size mechanical keyboard switch with 4 mm travel range, according to certain embodiments.

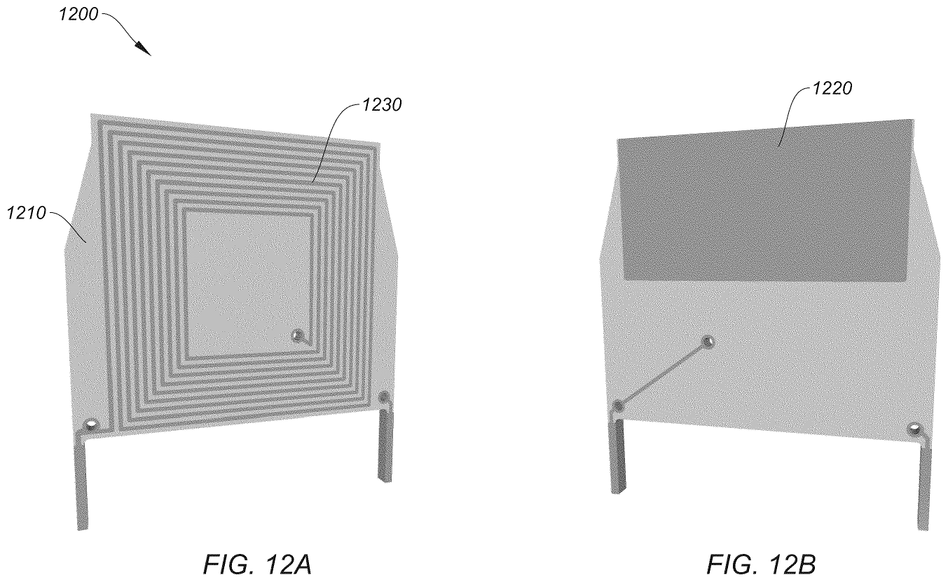

FIGS. 12A and 12B show the front and back sides of a vertically-oriented sensor 1200 with a fixed biasing conductive target 1220 coupled thereto, respectively, according to certain embodiments. Sensor 1200 can be an inductive sensor with antenna coil 1230 printed on a vertically oriented multi-layer rigid or flexible PCB 1210. In some aspects, fixed biasing conductive target 1220 can be directly printed on one of the layers. FIG. 12A shows the front side of PCB 1210 with antenna coil 1230 printed thereon. FIG. 12B shows the back side of PCB 1210 with fixed biasing conductive target 1220 printed thereon.

FIGS. 13A-13C show aspects of a key structure 1300 that can detect both travel and force using a single vertically oriented antenna, according to certain embodiments. Key structure 1300 includes a plunger 1310 and a moving target 1320 (e.g., a conductor) coupled thereto, vertically-oriented and extended sensor (e.g., inductive antenna) 1330 coupled to a front side of PCB 1350, and a fixed metal target 1325 coupled to a back side of PCB 1350. In operation, key structure 1300 may operate similarly to FIGS. 11B-11C during the travel phase of operation (e.g., 0˜4 mm). Once moving target 1320 reaches the bottom of the travel phase, a mechanism inside the switch can push the target laterally against sensor 1330, proportional to the force applied to plunger 1310.

FIGS. 13D-13F how aspects of another key structure that can detect both travel and fore using a single vertically oriented antenna, according to certain embodiments. In such cases, the light gray structure can be different part from the plunger. When the plunger is depressed along a central guide, the structure can follow one or more ramps and be pushed to the garget. By designing the slope with a particular angle, the X vs. Y characteristics of the key press can be tuned accordingly, as would be appreciated by one of ordinary skill in the art with the benefit of this disclosure. Another option is to use a compliant mechanism to generate an X motion with the plunger pressed.

### Embodiments of Horizontal-Only Sensing Systems

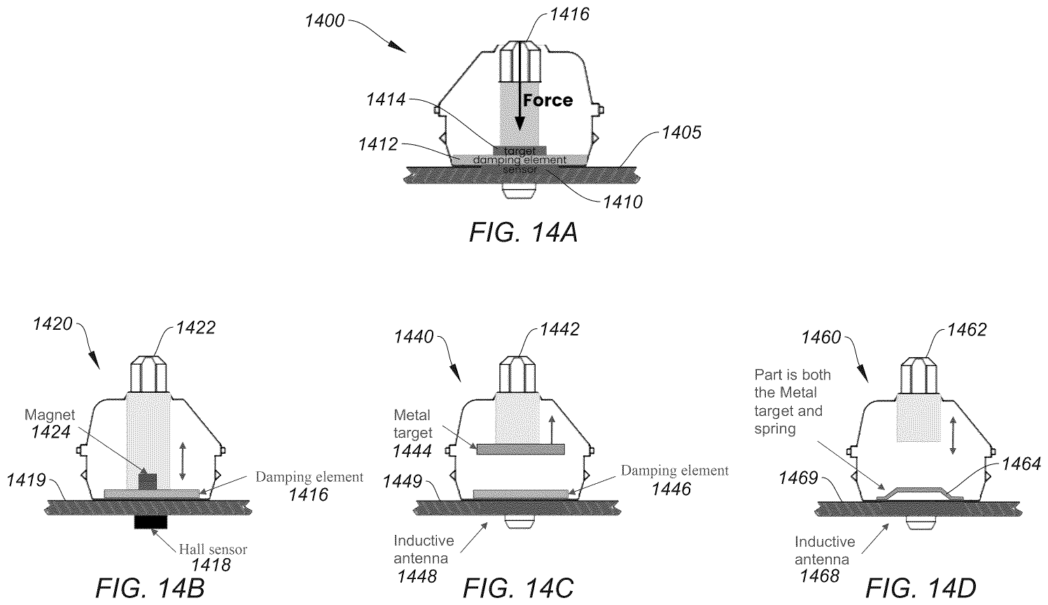

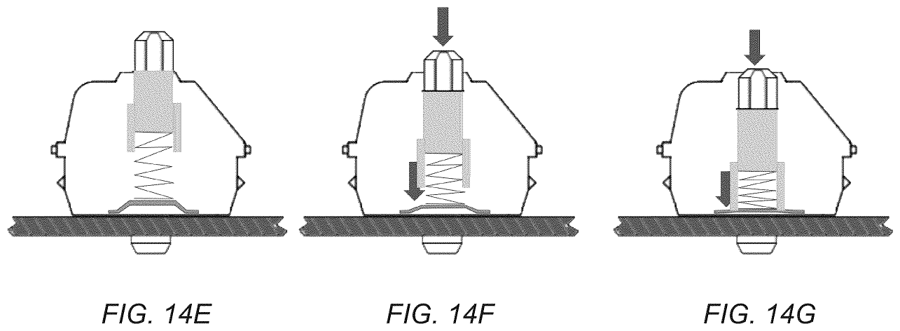

In many of the embodiments described above, the horizontally configured sensor and corresponding target are often used for force sensing. FIG. 14A shows a key structure 1400, according to certain embodiments. Key structure 1400 includes a horizontally oriented sensor 1410 configured on a PCB 1405, dampening element 1412, and target 1414 coupled to plunger 1416. As a downward force is applied to plunger 1416, the target 1414 is sensed by sensor 1410 with high sensitivity over the small compression range (i.e., small displacement of target 1414) of dampening element 1412. Horizontally oriented target 1414 can be coupled to plunger 1416 or dampening element 1412, according to certain embodiments.

For embodiments where target 1414 is coupled to the plunger, key structure 1400 can further be configured for travel sensing using the same sensor 1410, which may be well-suited for low profile switches with travel ranges of 2 mm or less.

Some embodiments may have the target coupled to the dampening element, which compresses once the plunger makes contact. In this case, the target can always be at or near the optimal range and is deformed during the force portion of the interaction. The target can be a dedicated metal target that deforms, or it can have dual functions as a target and return spring to return the key to an unpressed state. In these embodiments, orthogonal sensor arrangements (see, e.g., FIGS. 7A-7B) are better suited as the horizontal target will always be close to the sensor, thus biasing the sensor signal to be more sensitive.

FIG. 14B shows a key structure 1420, according to certain embodiments. Key structure 1420 includes a plunger 1422, a magnet 1424 (target) coupled to the bottom of plunger 1422, dampening element 1416 coupled to the top of PCB 1419, and Hall sensor 1418 coupled to the bottom of PCB 1419, according to certain embodiments. In operation, Hall sensor 1418 detects magnet 1424 as plunger 1422 is depressed.

FIG. 14C shows a key structure 1440, according to certain embodiments. Key structure 1440 includes a plunger 1442, a metal target 1444 coupled to the bottom of plunger 1442, dampening element 1446 coupled to the top of PCB 1449, and inductive antenna 1448 integrated with or coupled to PCB 1449, according to certain embodiments. In operation, inductive antenna 1448 detects metal target 1444 as plunger 1442 is depressed.

FIG. 14D shows a key structure 1460 with a combined target/dampening element, according to certain embodiments. Key structure 1460 includes a plunger 1462, a metal target/dampening element 1464 coupled to the top of PCB 1469, and inductive antenna 1468 integrated with or coupled to PCB 1469. In operation, inductive antenna 1468 detects metal target 1444 as plunger 1442 is depressed. Metal target 1444 can be used as a dampening element due to its spring architecture, and due to the absence of the compressible dampening element, target 1444 can move closer to inductive antenna 1468 and thus allow further improved sensitivity. Metal target 1444 can be mounted inside the switch, soldered to a top layer of the PCB, or attached at the bottom of the PCB, like an added module for force sensing using the plunger of the switch to apply force on it. FIGS. 14E-14G show how key structure 1460 operates as the spring pushes the bottom sensing target closer to the horizontal antenna during the travel phase (first range of motion) and presses it harder during the force phase (second range of motion), according to certain embodiments.

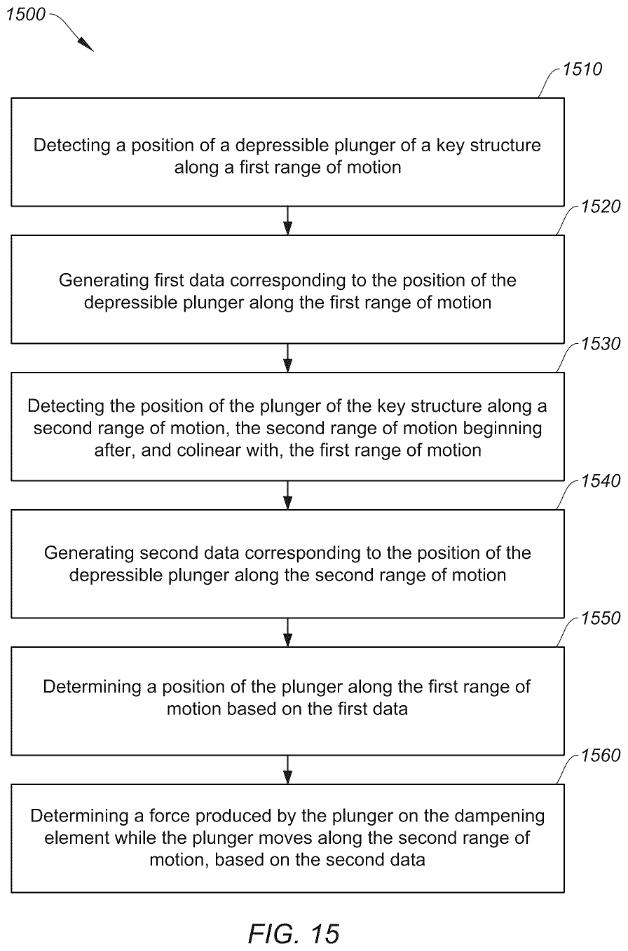

FIG. 15 is a simplified flow chart showing aspects of method 1500 for travel and force sensing in a key structure with an analog switch architecture, according to certain embodiments. Method 1500 can be performed by processing logic that may comprise of hardware (circuitry, dedicated logic, etc.), software operating on appropriate hardware (such as a general-purpose computing system or a dedicated machine), firmware (embedded software), or any combination thereof. In certain embodiments, method 1500 can be performed by aspects of system 200, as would be appreciated by one of ordinary skill in the art with the benefit of this disclosure.

At operation 1510, method 1500 can include detecting, by a first sensing section of a sensing element that is controlled by one or more processors of the keyboard device, a position of a depressible plunger of a key structure along a first range of motion, according to certain embodiments.

At operation 1520, method 1500 can include generating first data, by the sensing element, corresponding to the position of the depressible plunger along the first range of motion, according to certain embodiments.

At operation 1530, method 1500 can include detecting, by a second sensing section of the sensing element, the position of the plunger of the key structure along a second range of motion, the second range of motion beginning after, and colinear with, the first range of motion, according to certain embodiments. In some aspects, a dampening element is configured such that the depressible plunger contacts the dampening element at the end of the first range of motion and the beginning of the second range of motion. The depressible element may be compressed as the depressible plunger moves farther along the second range of motion.

At operation 1540, method 1500 can include generating second data, by the sensing element, corresponding to the position of the depressible plunger along the second range of motion, according to certain embodiments.

At operation 1550, method 1500 can include determining the position of the plunger along the first range of motion based on the first data, according to certain embodiments.

At operation 1560, method 1500 can include determining a force produced by the plunger on the dampening element while the plunger moves along the second range of motion, based on the second data, according to certain embodiments. In some cases, the sensing element can be multiple sensing elements (see, e.g., FIG. 7A) or a single sensing element (see, e.g., FIGS. 7B, 7C, 11A-C, 13A-C, and 14A-C). In some embodiments, the first sensing section of the sensing element is configured to be extended vertically and parallel to the first and second ranges of motion (see, e.g., FIG. 7B). In some cases, the second sensing section of the sensing element is configured to extend horizontally and perpendicular to the first and second ranges of motion.

In some implementations, the keyboard device comprises of a printed circuit board (PCB) having a (rigid or flexible) substrate, where the sensing element is configured on, coupled to, or integrated with the substrate. The sensing element can be comprised of a single inductive coil that spans both the first and second sensing sections of the sensing element such that portions of the single inductive coil are oriented 90° relative to one another. Although an inductive sensor is described in this example, one of ordinary skill in the art with the benefit of this disclosure, alternatively or additionally, can include an optical, magnetic, or other suitable sensing system.

In some cases, the keyboard device further comprises a first PCB and a second PCB (see, e.g., FIG. 8B), where the first sensing section includes a first inductive coil integrated with the first PCB, the second sensing section includes a second inductive coil integrated with the second PCB, the first inductive coil and second inductive coil are connected in series (or parallel), and the first PCB is oriented orthogonally with respect to the second PCB.

In some cases, the keyboard device further includes a fixed target that can be defined as a electrically conductive structure configured vertically and parallel to at least a portion of the first sensing section of the sensing element, the electrically conductive structure operable to bias a sensitivity of the sensing element along the first range of motion. The biasing of the electrically conductive structure can increase the linearity of the sensitivity of the sensing element along the first range of motion. In some cases, a PCB can have the first inductive coil integrated on the first side of the PCB closest to the plunger, and the electrically conductive structure (fixed target) can be configured on a second side of the PCB that is opposite the first side.

It should be appreciated that the specific steps illustrated in FIG. 15 provide a particular method 1500 for travel and force sensing in a key structure with an analog switch architecture, according to certain embodiments. Other sequences of steps may also be performed according to alternative embodiments. Furthermore, additional steps may be added or removed depending on the particular application. Any combination of changes can be used and one of ordinary skill in the art with the benefit of this disclosure would understand the many variations, modifications, and alternative embodiments thereof.

Numerous specific details are set forth herein to provide a thorough understanding of the claimed subject matter. However, those skilled in the art will understand that the claimed subject matter may be practiced without these specific details. In other instances, methods, apparatuses, or systems that would be known by one of ordinary skill have not been described in detail so as not to obscure the claimed subject matter. The various embodiments illustrated and described are provided merely as examples to illustrate various features of the claims. However, features shown and described with respect to any given embodiment are not necessarily limited to the associated embodiment and may be used or combined with other embodiments that are shown and described. Further, the claims are not intended to be limited by any one example embodiment.

While the present subject matter has been described in detail with respect to specific embodiments thereof, it will be appreciated that those skilled in the art, upon attaining an understanding of the foregoing may readily produce alterations to, variations of, and equivalents to such embodiments. Accordingly, it should be understood that the present disclosure has been presented for purposes of example rather than limitation, and does not preclude the inclusion of such modifications, variations, and/or additions to the present subject matter as would be readily apparent to one of ordinary skill in the art. Indeed, the methods and systems described herein may be embodied in a variety of other forms; furthermore, various omissions, substitutions, and changes in the form of the methods and systems described herein may be made without departing from the spirit of the present disclosure. The accompanying claims and their equivalents are intended to cover such forms or modifications as would fall within the scope and spirit of the present disclosure.

Although the present disclosure provides certain example embodiments and applications, other embodiments that are apparent to those of ordinary skill in the art, including embodiments which do not provide all of the features and advantages set forth herein, are also within the scope of this disclosure. Accordingly, the scope of the present disclosure is intended to be defined only by reference to the appended claims.

Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provide a result conditioned on one or more inputs. Suitable computing devices include multi-purpose microprocessor-based computer systems accessing stored software that programs or configures the computing system from a general-purpose computing apparatus to a specialized computing apparatus implementing one or more embodiments of the present subject matter. Any suitable programming, scripting, or other type of language or combinations of languages may be used to implement the teachings contained herein in software to be used in programming or configuring a computing device.

Embodiments of the methods disclosed herein may be performed in the operation of such computing devices. The order of the blocks presented in the examples above can be varied—for example, blocks can be re-ordered, combined, and/or broken into sub-blocks. Certain blocks or processes can be performed in parallel.

Conditional language used herein, such as, among others, “can,” “could,” “might,” “may,” “e.g.,” and the like, unless specifically stated otherwise, or otherwise understood within the context as used, is generally intended to convey that certain examples include, while other examples do not include, certain features, elements, and/or steps. Thus, such conditional language is not generally intended to imply that features, elements and/or steps are in any way required for one or more examples or that one or more examples necessarily include logic for deciding, with or without author input or prompting, whether these features, elements and/or steps are included or are to be performed in any particular example.

The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Similarly, the use of “based at least in part on” is meant to be open and inclusive, in that a process, step, calculation, or other action “based at least in part on” one or more recited conditions or values may, in practice, be based on additional conditions or values beyond those recited. Headings, lists, and numbering included herein are for case of explanation only and are not meant to be limiting.

The various features and processes described above may be used independently of one another or may be combined in various ways. All possible combinations and sub-combinations are intended to fall within the scope of the present disclosure. In addition, certain methods or process blocks may be omitted in some embodiments. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed examples. Similarly, the example systems and components described herein may be configured differently than described. For example, elements may be added to, removed from, or rearranged compared to the disclosed examples.

What is claimed is:

1. A key structure comprising:
one or more processors;
a depressible plunger configured to travel along a range of motion including:
a first range of motion; and
a second range of motion that begins after, and is colinear with, the first range of motion;
a dampening element configured such that the depressible plunger contacts the dampening element at an end of the first range of motion and a beginning of the second range of motion, wherein the depressible element compresses as the depressible plunger moves farther 9 along the second range of motion; and
a sensing element including:
a first sensing section configured to detect movement of the depressible plunger along the first range of motion and generate corresponding first data; and
a second sensing section configured to detect movement of the depressible plunger along the second range of motion and generate corresponding second data,
wherein the one or more processors are configured to:
determine a position of the plunger along the first range of motion based on the first data; and
determine a force produced by the plunger on the dampening element,
while the plunger moves along the second range of motion, based on the second data.

2. The key structure of claim 1 wherein the sensing element is a single sensing element.

3. The key structure of claim 2 wherein the first sensing section of the sensing element is configured to be extend vertically and parallel to the first and second ranges of motion.

4. The key structure of claim 3 wherein the second sensing section of the sensing element is configured to extend horizontally and perpendicular to the first and second ranges of motion.

5. The key structure of claim 4 further comprising a printed circuit board (PCB) having a flexible substrate,
wherein the sensing element is configured on the flexible substrate PCB, and
wherein the sensing element is comprised of a single inductive coil that spans 4 both the first and second sensing sections of the sensing element such that portions of the single 5 inductive coil are oriented 90° relative to one another.

6. The key structure of claim 4 further comprising:
a first printed circuit board (PCB); and
a second PCB,
wherein the first sensing section includes a first inductive coil integrated with the first PCB,
wherein the second sensing section includes a second inductive coil integrated with the second PCB,
wherein the first inductive coil and second inductive coil are connected in series, and
wherein the first PCB is oriented orthogonally with respect to the second PCB.

7. The key structure of claim 1 further comprising:
an electrically conductive structure configured vertically and parallel at least a portion of the first sensing section of the sensing element, the electrically conductive structure operable to bias a sensitivity of the sensing element along the first range of motion.

8. The key structure of claim 7 wherein the biasing of the electrically conductive structure increases a linearity of the sensitivity of the sensing element along the first range of motion.

9. The key structure of claim 7 further comprising a printed circuit board (PCB), wherein a first inductive coil is integrated on a first side of the PCB closest to the plunger, and wherein the electrically conductive structure is configured on a second side of the PCB that is opposite the first side.

10. The key structure of claim 1 wherein determining the force produced by the plunger on the dampening element while the plunger moves along the second range of motion corresponds to an amount that the dampening element is compressed by the plunger.

11. The key structure of claim 1 further comprising an electrically conductive target coupled to the plunger, wherein the first and second sensing sections of the sensing element detect the movement of the plunger along the first and second ranges of motion by detecting the movement of the electrically conductive target.

12. A method of operating a keyboard device comprising:
detecting, by a first sensing section of a sensing element that is controlled by one or more processors of the keyboard device, a position of a depressible plunger of a key structure along a first range of motion;
generating first data, by the sensing element, corresponding to the position of the depressible plunger along the first range of motion;
detecting, by a second sensing section of the sensing element, the position of the plunger of the key structure along a second range of motion, the second range of motion beginning after, and colinear with, the first range of motion,
wherein a dampening element is configured such that the depressible plunger contacts the dampening element at an end of the first range of motion and a beginning of the second range of motion, wherein the dampening element compresses as the depressible plunger moves farther along the second range of motion;
generating second data, by the sensing element, corresponding to the position of the depressible plunger along the second range of motion;
determining a position of the plunger along the first range of motion based on the first data; and
determining a force produced by the plunger on the dampening element while the plunger moves along the second range of motion, based on the second data.

13. The method of claim 12 wherein the sensing element is a single sensing element.

14. The method of claim 13 wherein the first sensing section of the sensing element is configured to be extend vertically and parallel to the first and second ranges of motion.

15. The method of claim 14 wherein the second sensing section of the sensing element is configured to extend horizontally and perpendicular to the first and second ranges of motion.

16. The method of claim 15 wherein the keyboard device comprises a printed circuit board (PCB) having a flexible substrate,
wherein the sensing element is configured on the flexible substrate PCB, and
wherein the sensing element is comprised of a single inductive coil that spans both the first and second sensing sections of the sensing element such that portions of the single inductive coil are oriented 90° relative to one another.

17. The method of claim 15 wherein the keyboard device further comprises:
a first printed circuit board (PCB); and
a second PCB,
wherein the first sensing section includes a first inductive coil integrated with the first PCB,
wherein the second sensing section includes a second inductive coil integrated with the second PCB,
wherein the first inductive coil and second inductive coil are connected in series, and
wherein the first PCB is oriented orthogonally with respect to the second PCB.

18. The method of claim 12 wherein the keyboard device further comprises:
an electrically conductive structure configured vertically and parallel at least a portion of the first sensing section of the sensing element, the electrically conductive structure operable to bias a sensitivity of the sensing element along the first range of motion.

19. The method of claim 18 wherein the biasing of the electrically conductive structure increases a linearity of the sensitivity of the sensing element along the first range of motion.

20. The method of claim 18 wherein the keyboard device further comprises:
a printed circuit board (PCB), wherein a first inductive coil is integrated on a first side of the PCB closest to the plunger, and wherein the electrically conductive structure is configured on a second side of the PCB that is opposite the first side.
